(19) United States
(12) Patent Application Publication
(10) Pub. No.: US 2020/0209759 A1
(43) Pub. Date: Jul. 2, 2020

(54) MIRROR FOR EXTREME ULTRAVIOLET LIGHT AND EXTREME ULTRAVIOLET LIGHT GENERATING APPARATUS

(71) Applicant: Gigaphoton Inc., Tochigi (JP)

(72) Inventors: Osamu WAKABAYASHI, Oyama-shi (JP); Yoshiyuki HONDA, Oyama-shi (JP)

(73) Assignee: Gigaphoton Inc., Tochigi (JP)

(21) Appl. No.: 16/814,700

(22) Filed: Mar. 10, 2020

Related U.S. Application Data
(63) Continuation of application No. PCT/JP2017/037992, filed on Oct. 20, 2017.

(51) Int. Cl. G03F 7/20

(52) U.S. Cl. CPC G03F 7/70016

(57) ABSTRACT

A mirror for extreme ultraviolet light includes: a substrate; a multilayer film provided on the substrate and configured to reflect extreme ultraviolet light; and a capping layer provided on the multilayer film, and the capping layer includes a photocatalyst layer containing a photocatalyst, a promotor layer arranged between the photocatalyst layer and the multilayer film and containing a metal for supporting a photocatalytic ability of the photocatalyst contained in the photocatalyst layer, and a barrier layer arranged between the promotor layer and the multilayer film and configured to prevent diffusion of the metal into the multilayer film.

### CROSS-REFERENCE TO RELATED APPLICATIONS

The present application is a continuation application of International Application No. PCT/JP2017/037992, filed on Oct. 20, 2017, the entire contents of which are hereby incorporated by reference.

### BACKGROUND

### 1. Technical Field

The present disclosure relates to a mirror for extreme ultraviolet light and an extreme ultraviolet light generating apparatus.

### 2. Related Art

Recently, miniaturization of semiconductor processes has involved increasing miniaturization of transfer patterns for use in photolithography of the semiconductor processes. In the next generation, microfabrication at 20 nm or less will be required. Thus, development of an exposure device is expected including a combination of an apparatus for generating extreme ultraviolet (EUV) light having a wavelength of about 13 nm and reduced projection reflection optics.

Three types of extreme ultraviolet light generating apparatuses have been proposed: an LPP (Laser Produced Plasma) type apparatus using plasma generated by irradiating a target substance with a laser beam, a DPP (Discharge Produced Plasma) type apparatus using plasma generated by discharge, and an SR (Synchrotron Radiation) type apparatus using synchrotron radiation light.

### LIST OF DOCUMENTS

### Patent Documents

Patent Document 1: Japanese Unexamined Patent Application Publication No. 2006-170811

Patent Document 2: International Patent Publication No. 2016/169731

Patent Document 3: US Published Patent Application No. 2003/0147058

Patent Document 4: US Published Patent Application No. 2016/0349412

Patent Document 5: International Patent Publication No. 2005/091887

### SUMMARY

A mirror for extreme ultraviolet light according to one aspect of the present disclosure may include: a substrate; a multilayer film provided on the substrate and configured to reflect extreme ultraviolet light; and a capping layer provided on the multilayer film. The capping layer may include a photocatalyst layer containing a photocatalyst, a promotor layer arranged between the photocatalyst layer and the multilayer film and containing a metal for supporting a photocatalytic ability of the photocatalyst contained in the photocatalyst layer, and a barrier layer arranged between the promotor layer and the multilayer film and configured to prevent diffusion of the metal into the multilayer film.

An extreme ultraviolet light generating apparatus according to one aspect of the present disclosure may include: a chamber; a droplet discharge unit configured to discharge a droplet of a target substance into the chamber; and a mirror for extreme ultraviolet light provided in the chamber. The mirror for extreme ultraviolet light may include a substrate, a multilayer film provided on the substrate and configured to reflect extreme ultraviolet light, and a capping layer provided on the multilayer film. The capping layer may include a photocatalyst layer containing a photocatalyst, a promotor layer arranged between the photocatalyst layer and the multilayer film and containing a metal for supporting a photocatalytic ability of the photocatalyst contained in the photocatalyst layer, and a barrier layer arranged between the promotor layer and the multilayer film and configured to prevent diffusion of the metal into the multilayer film.

### BRIEF DESCRIPTION OF THE DRAWINGS

With reference to the accompanying drawings, some embodiments of the present disclosure will be described below merely by way of example.

FIG. 1 diagrammatically shows a schematic exemplary configuration of an entire extreme ultraviolet light generating apparatus.

FIG. 2 diagrammatically shows a section of an EUV light reflective mirror of a comparative example.

FIG. 3 diagrammatically shows an estimated mechanism of a reaction between a gas supplied to a reflective surface and fine particles adhering to the reflective surface.

FIG. 4 diagrammatically shows an estimated mechanism of accumulation of fine particles of a target substance.

FIG. 5 diagrammatically shows a section of an EUV light reflective mirror of Embodiment 1.

FIG. 6 diagrammatically shows a section of an EUV light reflective mirror of Embodiment 2.

FIG. 7 diagrammatically shows a section of an EUV light reflective mirror of Embodiment 3.

### DESCRIPTION OF EMBODIMENTS

1. Overview
2. Description of extreme ultraviolet light generating apparatus

2.1 Overall configuration

2.2 Operation
3. Description of EUV light reflective mirror of comparative example

3.1 Configuration

3.2 Problem
4. Description of EUV light reflective mirror of Embodiment 1

4.1 Configuration

4.2 Effect
5. Description of EUV light reflective mirror of Embodiment 2

5.1 Configuration

5.2 Effect
6. Description of EUV light reflective mirror of Embodiment 3

6.1 Configuration

6.2 Effect

Now, with reference to the drawings, embodiments of the present disclosure will be described in detail.

The embodiments described below illustrate some examples of the present disclosure, and do not limit contents of the present disclosure. Also, all configurations and operations described in the embodiments are not necessarily essential as configurations and operations of the present disclosure.

The same components are denoted by the same reference numerals, and overlapping descriptions are omitted.

### 1. Overview

Embodiments of the present disclosure relate to a mirror used in an extreme ultraviolet light generating apparatus configured to generate light having a wavelength of extreme ultraviolet (EUV) light. Hereinafter, the extreme ultraviolet light is sometimes referred to as EUV light.

### 2. Description of Extreme Ultraviolet Light Generating Apparatus

2.1 Overall Configuration

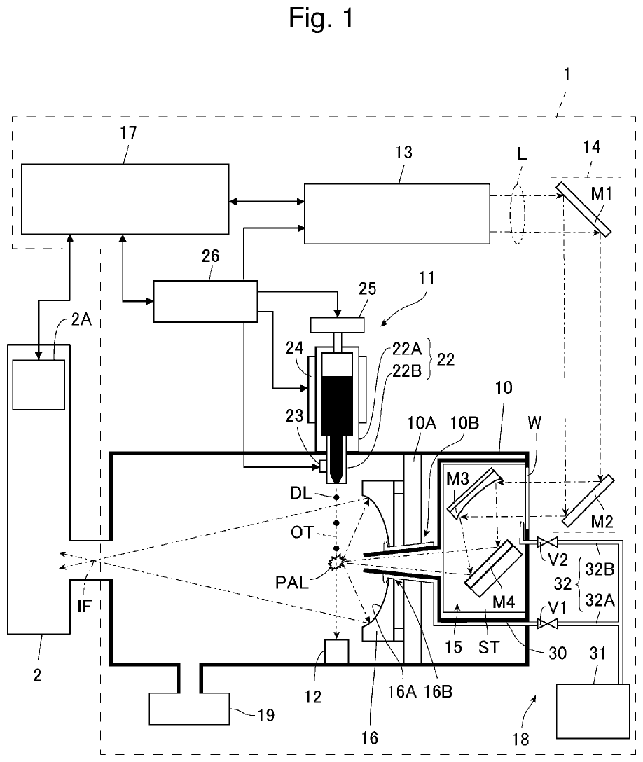

FIG. 1 diagrammatically shows a schematic exemplary configuration of an entire extreme ultraviolet light generating apparatus. As shown in FIG. 1, an extreme ultraviolet light generating apparatus 1 of this embodiment is used together with an exposure device 2. The exposure device 2 exposes a semiconductor wafer to EUV light generated by the extreme ultraviolet light generating apparatus 1, and includes a control unit 2A. The control unit 2A outputs a burst signal to the extreme ultraviolet light generating apparatus 1. The burst signal designates a burst period for generating the EUV light and an intermission period for stopping generation of the EUV light. For example, a burst signal to alternately repeat the burst period and the intermission period is output from the control unit 2A of the exposure device 2 to the extreme ultraviolet light generating apparatus 1.

The extreme ultraviolet light generating apparatus 1 includes a chamber 10. The chamber 10 is a container that can be sealed and reduced in pressure. A wall of the chamber 10 has at least one through-hole. The through-hole is closed by a window W. The window W is configured to transmit a laser beam L entering from outside the chamber 10. The chamber 10 may be divided by a partition plate 10A.

The extreme ultraviolet light generating apparatus 1 also includes a droplet discharge unit 11. The droplet discharge unit 11 is configured to discharge a droplet DL of a target substance into the chamber 10. The droplet discharge unit 11 may include, for example, a target ejector 22, a piezoelectric element 23, a heater 24, a pressure adjusting unit 25, and a droplet generation control unit 26.

The target ejector 22 includes a tank 22A removably mounted to the wall of the chamber 10, and a nozzle 22B connected to the tank 22A. The tank 22A stores the target substance. A material of the target substance may include tin, terbium, gadolinium, lithium, or xenon, or any combinations of two or more of them, but not limited thereto. At least a tip of the nozzle 22B is arranged in the chamber 10.

The piezoelectric element 23 is provided on an outer surface of the nozzle 22B of the target ejector 22. The piezoelectric element 23 is driven by power supplied from the droplet generation control unit 26, and vibrates at predetermined vibration intervals. The heater 24 is provided on an outer surface of the tank 22A of the target ejector 22. The heater 24 is driven by the power supplied from the droplet generation control unit 26, and heats the tank 22A of the target ejector 22 so as to reach a preset temperature. The preset temperature may be set by the droplet generation control unit 26, or by an input device outside the extreme ultraviolet light generating apparatus 1. The pressure adjusting unit 25 adjusts a gas supplied from a gas cylinder (not shown) to gas pressure designated by the droplet generation control unit 26. The gas at the gas pressure presses the molten target substance stored in the tank 22A of the target ejector 22.

A droplet-related signal is input to the droplet generation control unit 26. The droplet-related signal indicates information relating to the droplet DL such as a speed or a direction of the droplet DL. The droplet generation control unit 26 controls the target ejector 22 to adjust a discharge direction of the droplet DL based on the droplet-related signal. The droplet generation control unit 26 controls the pressure adjusting unit 25 to adjust the speed of the droplet DL based on the droplet-related signal. The control of the droplet generation control unit 26 is merely exemplary, and different control may be added as required.

The extreme ultraviolet light generating apparatus 1 further includes a droplet collecting unit 12. The droplet collecting unit 12 is configured to collect a droplet DL that has not been turned into plasma in the chamber 10 among droplets DL supplied into the chamber 10. For example, the droplet collecting unit 12 is provided on a trajectory OT of the droplet DL on a wall of the chamber 10 opposite to a wall to which the droplet discharge unit 11 is mounted.

The extreme ultraviolet light generating apparatus 1 further includes a laser unit 13, a beam transmission optical system 14, a laser beam condensing optical system 15, and an EUV light reflective mirror 16. The laser unit 13 emits a laser beam L having a predetermined pulse width. The laser unit 13 includes, for example, a solid-state laser or a gas laser. The solid-state laser includes, for example, an Nd:YAG laser, an Nd:YVO₄ laser, or a laser that outputs harmonic light thereof. The gas laser includes, for example, a CO₂ laser or an excimer laser.

The beam transmission optical system 14 is configured to transmit the laser beam L emitted from the laser unit 13 to the window W of the chamber 10. The beam transmission optical system 14 may include, for example, a plurality of mirrors M1, M2 configured to reflect the laser beam L. In the example in FIG. 1, two mirrors are provided, but one mirror or three or more mirrors may be provided. An optical element other than the mirror such as a beam splitter may be used.

The laser beam condensing optical system 15 is provided in the chamber 10 and is configured to focus, in a plasma generating region PAL, the laser beam L having entered the chamber 10 through the window W. In the plasma generating region PAL, the droplet DL is turned into plasma. The laser beam condensing optical system 15 may include, for example, a concave mirror M3 configured to reflect the laser beam L having entered the chamber 10 and to focus and guide the laser beam L in a reflecting direction, and a mirror M4 configured to reflect the laser beam L from the concave mirror M3 toward the plasma generating region PAL. The laser beam condensing optical system 15 may include a stage ST movable in three axial directions, and the stage ST may be moved to adjust a focusing position.

The EUV light reflective mirror 16 is a mirror for EUV light provided in the chamber 10 and configured to reflect EUV light generated when the droplet DL is turned into plasma in the plasma generating region PAL in the chamber 10. The EUV light reflective mirror 16 includes, for example, a spheroidal reflective surface that reflects the EUV light generated in the plasma generating region PAL, and is configured so that a first focal point is located in the plasma generating region PAL and a second focal point is located in an intermediate focal point IF. The EUV light reflective mirror 16 may have a through-hole 16B extending from a surface 16A that reflects the EUV light to a surface opposite to the surface 16A and including a central axis of the EUV light reflective mirror 16. The laser beam L emitted from the laser beam condensing optical system 15 may pass through the through-hole 16B. The central axis of the EUV light reflective mirror 16 may be a line passing through the first focal point and the second focal point or may be a rotation axis of a spheroid. When the chamber 10 is divided by the partition plate 10A as described above, the EUV light reflective mirror 16 may be secured to the partition plate 10A. In this case, the partition plate 10A may have a communication hole 10B communicating with the through-hole 16B in the EUV light reflective mirror 16. The EUV light reflective mirror 16 may include a temperature adjustor to maintain the EUV light reflective mirror 16 at a substantially constant temperature.

The extreme ultraviolet light generating apparatus 1 further includes an EUV light generation controller 17. The EUV light generation controller 17 generates the droplet-related signal based on a signal output from a sensor (not shown), and outputs the generated droplet-related signal to the droplet generation control unit 26 of the droplet discharge unit 11. The EUV light generation controller 17 also generates a light emission trigger signal based on the droplet-related signal and the burst signal output from the exposure device 2, and outputs the generated light emission trigger signal to the laser unit 13, thereby controlling a burst operation of the laser unit 13. The burst operation means an operation of emitting a continuous pulse laser beam L at predetermined intervals during a burst-on period and preventing emission of the laser beam L during a burst-off period. The control of the EUV light generation controller 17 is merely exemplary, and different control may be added as required. The EUV light generation controller 17 may perform the control of the droplet generation control unit 26.

The extreme ultraviolet light generating apparatus 1 further includes a gas supply unit 18. The gas supply unit 18 is configured to supply a gas, which reacts with fine particles generated when the droplet DL is turned into plasma, into the chamber 10. The fine particles include neutral particles and charged particles. When the material of the target substance stored in the tank 22A of the droplet discharge unit 11 is tin, the gas supplied from the gas supply unit 18 is a hydrogen gas or a gas containing hydrogen. In this case, tin fine particles are generated when the droplet DL of the target substance is turned into plasma, and the tin fine particles react with the hydrogen to generate stannane that is gas at room temperature. The gas supply unit 18 may include, for example, a cover 30, a gas storing unit 31, and a gas introducing pipe 32.

In the example in FIG. 1, the cover 30 is provided to cover the laser beam condensing optical system 15, and includes a truncated conical nozzle. The nozzle of the cover 30 is inserted through the through-hole 16B in the EUV light reflective mirror 16, and a tip of the nozzle protrudes from the surface 16A of the EUV light reflective mirror 16 and is directed toward the plasma generating region PAL. The gas storing unit 31 stores the gas that reacts with the fine particles generated when the droplet DL is turned into plasma. The gas introducing pipe 32 introduces the gas stored in the gas storing unit 31 into the chamber 10. As in the example in FIG. 1, the gas introducing pipe 32 may be divided into a first gas introducing pipe 32A and a second gas introducing pipe 32B.

In the example in FIG. 1, the first gas introducing pipe 32A is configured to adjust, with a flow regulating valve V1, a flow rate of the gas flowing from the gas storing unit 31 through the first gas introducing pipe 32A. In the example in FIG. 1, an output end of the first gas introducing pipe 32A is arranged along an outer wall surface of the nozzle of the cover 30 inserted through the through-hole 16B in the EUV light reflective mirror 16, and an opening of the output end is directed toward the surface 16A of the EUV light reflective mirror 16. Thus, the gas supply unit 18 can supply the gas along the surface 16A of the EUV light reflective mirror 16 toward an outer edge of the EUV light reflective mirror 16. In the example in FIG. 1, the second gas introducing pipe 32B is configured to adjust, with a flow regulating valve V2, a flow rate of the gas flowing from the gas storing unit 31 through the second gas introducing pipe 32B. In the example in FIG. 1, an output end of the second gas introducing pipe 32B is arranged in the cover 30, and an opening of the output end is directed toward an inner surface of the window W of the chamber 10. Thus, the gas supply unit 18 can introduce the gas along an inner surface of the chamber 10 at the window W, and supply the gas from the nozzle of the cover 30 toward the plasma generating region PAL.

The extreme ultraviolet light generating apparatus 1 further includes an exhaust unit 19. The exhaust unit 19 is configured to exhaust a residual gas in the chamber 10. The residual gas contains the fine particles generated when the droplet DL is turned into plasma, a product generated by the reaction between the fine particles and the gas supplied from the gas supply unit 18, and an unreacted gas. The exhaust unit 19 may maintain the inside of the chamber 10 at substantially constant pressure.

2.2 Operation

The gas supply unit 18 supplies, into the chamber 10, the gas that reacts with the fine particles generated when the droplet DL is turned into plasma. The exhaust unit 19 maintains the inside of the chamber 10 at substantially constant pressure. The pressure in the chamber 10 is, for example, within the range of 20 to 100 Pa, preferably 15 to 40 Pa.

In this state, the EUV light generation controller 17 controls the droplet discharge unit 11 to discharge the droplet DL of the target substance into the chamber 10, and controls the laser unit 13 to perform the burst operation. A diameter of the droplet DL supplied from the droplet discharge unit 11 to the plasma generating region PAL is, for example, 10 to 30 μm.

The laser beam L emitted from the laser unit 13 is transmitted to the window W of the chamber 10 by the beam transmission optical system 14, and enters the chamber 10 through the window W. The laser beam L having entered the chamber 10 is focused in the plasma generating region PAL by the laser beam condensing optical system 15, and is applied to at least one droplet DL having reached the plasma generating region PAL from the droplet discharge unit 11. The droplet DL irradiated with the laser beam L is turned into plasma, and light including EUV light is radiated from the plasma. The EUV light is selectively reflected by the reflective surface of the EUV light reflective mirror 16 and is emitted to the exposure device 2. A plurality of laser beams may be applied to one droplet DL.

When the droplet DL is turned into plasma to generate the fine particles as described above, the fine particles are dispersed in the chamber 10. One part of the fine particles dispersed in the chamber 10 move toward the nozzle of the cover 30 of the gas supply unit 18. When the gas introduced from the second gas introducing pipe 32B of the gas supply unit 18 moves from the nozzle of the cover 30 toward the plasma generating region PAL as described above, the fine particles dispersed in the plasma generating region PAL can be prevented from entering the cover 30. Even if the fine particles enter the cover 30, the gas introduced from the second gas introducing pipe 32B reacts with the fine particles, thereby preventing the fine particles from adhering to the window W, the concave mirror M3, the mirror M4, or the like.

Another part of the fine particles dispersed in the chamber 10 move toward the surface 16A of the EUV light reflective mirror 16. The fine particles moving toward the surface 16A of the EUV light reflective mirror 16 react with the gas supplied from the gas supply unit 18 to generate a predetermined product. As described above, when the gas supply unit 18 supplies the gas along the surface 16A of the EUV light reflective mirror 16, the gas and the fine particles can more efficiently react with each other than when no gas is supplied along the surface 16A.

When the material of the target substance is tin and the gas supplied from the gas supply unit 18 contains hydrogen as described above, the tin fine particles react with the hydrogen to generate stannane that is gas at room temperature as described above. However, stannane is easily dissociated from hydrogen at high temperature to generate tin fine particles. Thus, when the product is stannane, the EUV light reflective mirror 16 is preferably maintained at a temperature of 60° C. or lower to prevent dissociation from hydrogen. The temperature of the EUV light reflective mirror 16 is more preferably 20° C. or lower.

The product obtained by the reaction with the gas supplied from the gas supply unit 18, together with an unreacted gas, flows in the chamber 10. At least part of the product and the unreacted gas flowing in the chamber 10 flow, as a residual gas, into the exhaust unit 19 on an exhaust flow of the exhaust unit 19. The residual gas having flowed into the exhaust unit 19 is subjected to a predetermined exhaust process such as detoxification in the exhaust unit 19. This prevents the fine particles or the like generated when the droplet DL is turned into plasma from accumulating on the surface 16A of the EUV light reflective mirror 16 or the like. This also prevents the fine particles or the like from remaining in the chamber 10.

### 3. Description of EUV Light Reflective Mirror of Comparative Example

Next, an EUV light reflective mirror of a comparative example of the extreme ultraviolet light generating apparatus will be described. Components similar to those described above are denoted by the same reference numerals, and overlapping descriptions are omitted unless otherwise stated.

3.1 Configuration

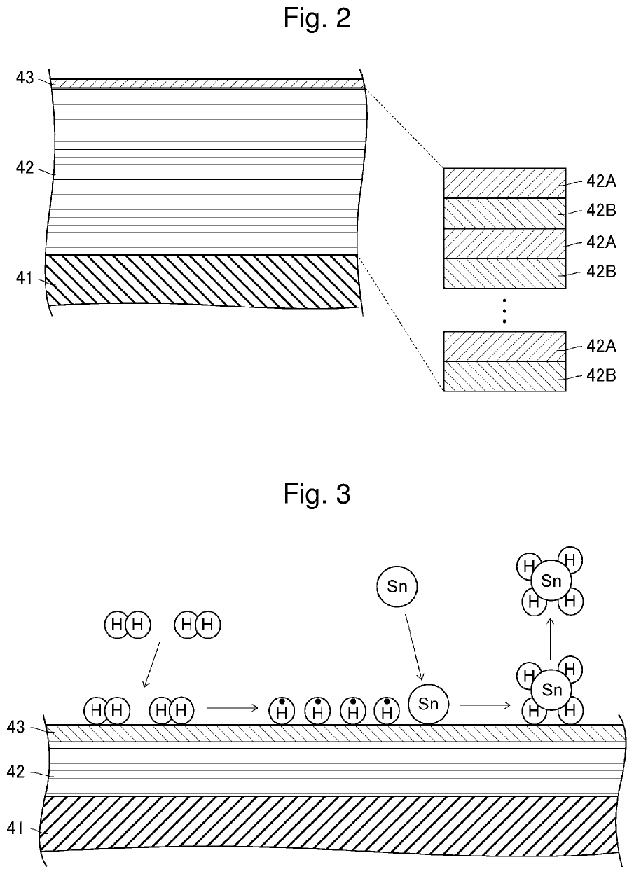

FIG. 2 diagrammatically shows a section of an EUV light reflective mirror 16 of a comparative example. As shown in FIG. 2, the EUV light reflective mirror 16 of the comparative example includes a substrate 41, a multilayer film 42, and a capping layer 43.

The multilayer film 42 reflects EUV light and is provided on the substrate 41. The multilayer film 42 includes a first layer 42A containing a first material and a second layer 42B containing a second material alternately stacked. A reflective surface of the EUV light reflective mirror 16 includes an interface between the first layer 42A and the second layer 42B of the multilayer film 42, and a surface of the multilayer film 42. The surface of the multilayer film 42 is an interface between the multilayer film 42 and the capping layer 43. As long as the multilayer film 42 reflects the EUV light, the first material and the second material are not limited. For example, the first material may be Mo and the second material may be Si, or the first material may be Ru and the second material may be Si. Alternatively, for example, the first material may be Be and the second material may be Si, or the first material may be Nb and the second material may be Si. Alternatively, for example, the first material may be Mo and the second material may be RbSiH₃, or the first material may be Mo and the second material may be RbₓSi_{y}.

The capping layer 43 protects the multilayer film 42. A material of the capping layer 43 is, for example, TiO₂. The material of the capping layer 43 may be other than TiO₂.

3.2 Problem

Among fine particles generated when a droplet DL is turned into plasma, fine particles moving toward a surface of the capping layer 43 that is a surface 16A of the EUV light reflective mirror 16 react with a gas supplied from a gas supply unit 18 to generate a predetermined product as described above. An estimated mechanism of this reaction is shown in FIG. 3. FIG. 3 shows a case where a material of a target substance is tin and the gas supplied from the gas supply unit 18 contains hydrogen.

As shown in FIG. 3, when the gas supplied from the gas supply unit 18 contains hydrogen molecules, the hydrogen molecules are adsorbed on the surface of the capping layer 43. When the hydrogen molecules are irradiated with light including EUV light, the hydrogen molecules generate hydrogen radicals. The fine particles moving toward the surface 16A of the EUV light reflective mirror 16 react with the hydrogen radicals to generate stannane that is gas at room temperature as expressed by Expression (1) below:

Sn+4H•→SnH₄ (1)

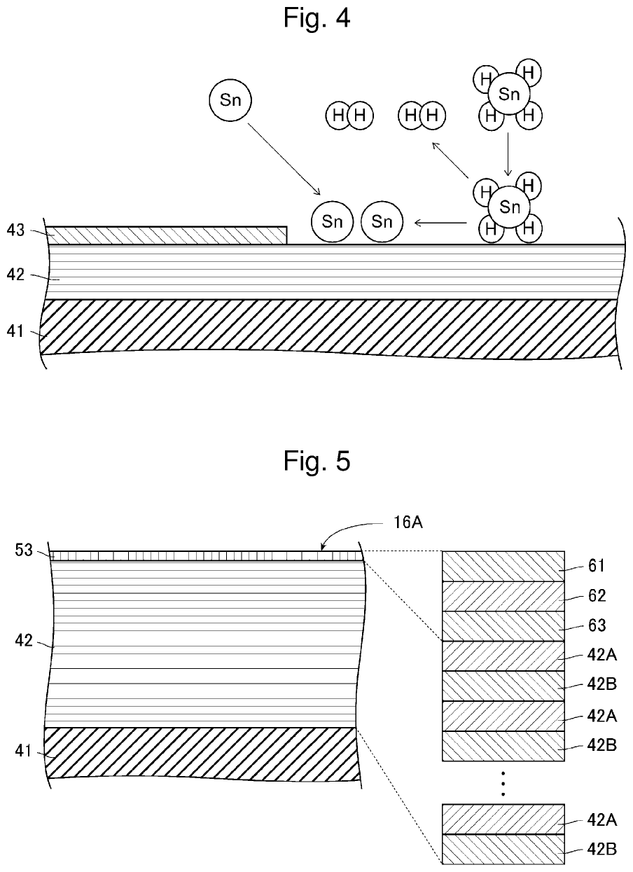

However, the fine particles may collide with and wear away the capping layer 43 to locally expose the multilayer film 42 from the capping layer 43. In this case, the fine particles easily accumulate on the multilayer film 42. An estimated mechanism of accumulation of the fine particles of the target substance is shown in FIG. 4. Like FIG. 3, FIG. 4 shows a case where the material of the target substance is tin and the gas supplied from the gas supply unit 18 contains hydrogen.

As shown in FIG. 4, when the multilayer film 42 is exposed from the capping layer 43, the stannane is adsorbed on the multilayer film 42. When the stannane is adsorbed, a reverse reaction of Expression (1) occurs, and the hydrogen molecules are released from the stannane to generate tin fine particles, which remain on the multilayer film 42. When the stannane is further adsorbed on the tin fine particles remaining on the multilayer film 42, the reverse reaction of Expression (1) occurs, and further tin fine particles remain on the tin fine particles remaining on the multilayer film 42. In this way, the tin fine particles accumulate on the multilayer film 42. Although such a mechanism is an estimation as described above, an experiment has shown that the fine particles easily accumulate on the multilayer film 42 exposed from the capping layer 43.

An experiment has also shown that the fine particles may accumulate on the surface of the capping layer 43 before the surface is worn away by collision with the fine particles, or on a new surface resulting from the wearing away of the surface of the capping layer 43. A reason for this may be that the fine particles accumulate on the surface of the capping layer 43 at high speed and the reverse reaction predominates over the reaction of Expression (1). Another reason may be that a concentration of the stannane is high near the surface of the capping layer 43 and the reverse reaction predominates over the reaction of Expression (1). A further reason may be that a surface temperature of the capping layer 43 increases and thus the reverse reaction predominates over the reaction of Expression (1).

In this way, the fine particles may accumulate on the surface of the capping layer 43 or on the multilayer film 42 exposed from the capping layer 43. In this case, the accumulating fine particles may reduce reflectance of the EUV light on the EUV light reflective mirror 16.

Then, embodiments described below illustrate an EUV light reflective mirror 16 that can prevent a reduction in reflectance of EUV light.

### 4. Description of EUV Light Reflective Mirror of Embodiment 1

Next, a configuration of an EUV light reflective mirror 16 of Embodiment 1 will be described. Components similar to those described above are denoted by the same reference numerals, and overlapping descriptions are omitted unless otherwise stated. A case where a material of a target substance is tin and a gas supplied from a gas supply unit 18 contains hydrogen will be described below as an example.

4.1 Configuration

FIG. 5 diagrammatically shows a section of the EUV light reflective mirror 16 of Embodiment 1. As shown in FIG. 5, the EUV light reflective mirror 16 of this embodiment is different from the EUV light reflective mirror 16 of the comparative example in that the former includes a capping layer 53 including a plurality of layers while the latter includes the capping layer 43 including a single layer. The capping layer 53 of this embodiment transmits EUV light, and includes a photocatalyst layer 61, a promotor layer 62, and a barrier layer 63.

The photocatalyst layer 61 contains a photocatalyst. A material of the photocatalyst layer 61 is not limited as long as it contains a photocatalyst. For example, the photocatalyst layer 61 may contain, as a photocatalyst, any of TiO₂, ZrO₂, Fe₂O₃, Cu₂O, In₂O₃, WO₃, Fe₂TiO₃, PbO, V₂O₅, FeTiO₃, Bi₂O₃, Nb₂O₃, SrTiO₃, ZnO, BaTiO₃, CaTiO₃, KTiO₃, and SnO₂. The photocatalyst layer 61 preferably contains, as a photocatalyst, any of TiO₂, ZrO₂, and WO₃. As long as the photocatalyst layer 61 mainly contains such a photocatalyst, the photocatalyst layer 61 may contain, together with the photocatalyst, additives, impurities, or the like in a smaller amount than the photocatalyst. The photocatalyst contained in the photocatalyst layer 61 may have an amorphous structure or a polycrystalline structure, but preferably has a polycrystalline structure in terms of increasing a photocatalytic ability of the photocatalyst. A density of TiO₂ is 4.23 g/cm³. A density of ZrO₂ is 5.68 g/cm³. A density of Fe₂O₃ is 5.24 g/cm³. A density of Cu₂O is 6 g/cm³. A density of In₂O₃ is 7.18 g/cm³. A density of WO₃ is 7.16 g/cm³. A density of Nb₂O₃ is 4.6 g/cm³. A density of ZnO is 5.61 g/cm³. A density of BaTiO₃ is 6.02 g/cm³. A density of CaTiO₃ is 3.98 g/cm³. A density of KTiO₃ is 7.015 g/cm³. A density of SnO₂ is 6.95 g/cm³.

A thickness of the photocatalyst layer 61 is preferably, for example, equal to or larger than a thickness of a minimum structural unit of the photocatalyst contained in the photocatalyst layer 61 and 5 nm or smaller. Herein, a thickness of a layer is obtained in such a manner that thicknesses at any three or more points of the layer are measured to obtain an arithmetic mean value of the measured thicknesses. For example, when the photocatalyst is TiO₂, a thickness of a minimum structural unit of the photocatalyst is 0.2297 nm.

Surface roughness of the photocatalyst layer 61 that is a surface 16A of the EUV light reflective mirror 16 is preferably of an Ra value of 0.5 nm or lower, and more preferably 0.3 nm or lower. Surface roughness may be measured by, for example, a method described in APPLIED OPTICS Vol. 50, No. 9/20 March (2011) C164-C171.

The promotor layer 62 is arranged between the photocatalyst layer 61 and the multilayer film 42, and contains a metal for supporting the photocatalytic ability of the photocatalyst contained in the photocatalyst layer 61. A different layer may be provided between the photocatalyst layer 61 and the promotor layer 62, but as shown in the example in FIG. 5, the promotor layer 62 is preferably in contact with the photocatalyst layer.

The metal contained in the promotor layer 62 is not particularly limited as long as it supports the photocatalytic ability of the photocatalyst, and a plurality of types of metals may be contained in the promotor layer 62. Examples of such a metal may include, for example, Ru, Rh, Pd, Os, Ir, and Pt that are platinum group metals. The promotor layer 62 preferably contains any of Os, Ir, and Pt. As long as the promotor layer 62 mainly contains such a metal, the promotor layer 62 may contain, together with the metal, additives, impurities, or the like in a smaller amount than the metal. A density of the promotor layer 62 is preferably higher than a density of the photocatalyst layer 61 in terms of preventing transmission of hydrogen radicals. A density of Ru is 12.45 g/cm³. A density of Rh is 12.41 g/cm³. A density of Pd is 12.023 g/cm³. A density of Os is 22.59 g/cm³. A density of Ir is 22.56 g/cm³. A density of Pt is 21.45 g/cm³.

A thickness of the promotor layer 62 is, for example, equal to or larger than an atomic diameter of the metal contained in the promotor layer 62 and 2 nm or smaller. The thickness of the promotor layer 62 is preferably smaller than the thickness of the photocatalyst layer 61. The photocatalytic ability of the photocatalyst does not tend to significantly change with changing amount of a promotor. Thus, the thickness of the promotor layer 62 smaller than the thickness of the photocatalyst layer 61 can prevent a reduction in the photocatalytic ability of the photocatalyst and reduce a thickness of the capping layer 53 as compared to a case where the thickness of the promotor layer 62 is equal to or larger than the thickness of the photocatalyst layer 61. This can prevent a reduction in the photocatalytic ability of the photocatalyst and improve transmittance of the EUV light through the capping layer 53. When the thickness of the promotor layer 62 is assumed as 1, the thickness of the photocatalyst layer 61 is more preferably 4 to 10. The promotor layer 62 preferably more reliably prevents transmission of the hydrogen radicals than the photocatalyst layer 61. In this case, the density of the promotor layer 62 is preferably higher than the density of the photocatalyst layer 61.

The barrier layer 63 prevents diffusion of the metal contained in the promotor layer 62 into the multilayer film 42, and is arranged between the promotor layer 62 and the multilayer film 42. A different layer may be provided between the barrier layer 63 and the promotor layer 62, but as shown in FIG. 5, the barrier layer 63 is preferably in contact with the promotor layer 62. In this embodiment, the example of the barrier layer 63 arranged in contact with the multilayer film 42 is shown as in FIG. 5, but a different layer may be provided between the barrier layer 63 and the multilayer film 42.

A material of the barrier layer 63 is not limited as long as it prevents diffusion of the metal contained in the promotor layer 62 into the multilayer film 42. For example, the barrier layer 63 may contain a photocatalyst. When the barrier layer 63 contains the photocatalyst, the metal contained in the promotor layer 62 preferably supports a photocatalytic ability of the photocatalyst contained in the barrier layer 63. In this case, the barrier layer 63 is more preferably arranged in contact with the promotor layer 62 as described above. When the barrier layer 63 contains the photocatalyst, the photocatalyst contained in the barrier layer 63 and the photocatalyst contained in the photocatalyst layer 61 may be the same material or different materials. Even if the photocatalyst contained in the barrier layer 63 and the photocatalyst contained in the photocatalyst layer 61 are different materials, the metal contained in the promotor layer 62 preferably supports the photocatalytic ability of the photocatalyst contained in the photocatalyst layer 61 and the photocatalytic ability of the photocatalyst contained in the barrier layer 63.

The thickness of the photocatalyst layer 61 is preferably larger than the thickness of the barrier layer 63. In this case, even if the capping layer 53 is worn away by collision with tin fine particles as described above, the photocatalyst layer 61 can remain on the promotor layer 62 as much as possible. Further, transmittance of the EUV light through the photocatalyst layer 61 is preferably higher than transmittance of the EUV light through the barrier layer 63. Generally, transmittance of the EUV light tends to decrease with increasing thickness of the photocatalyst layer 61, and reflectance of the EUV light on the multilayer film 42 tends to decrease. However, if the transmittance of the EUV light through the photocatalyst layer 61 on the side of the surface 16A of the EUV light reflective mirror 16 is higher than the transmittance of the EUV light through the barrier layer 63, an excessive reduction in the transmittance of the EUV light can be prevented even with a relatively large thickness of the photocatalyst layer 61. In this way, when the thickness of the photocatalyst layer 61 is larger than the thickness of the barrier layer 63, the photocatalyst layer 61 preferably contains ZrO₂, and the barrier layer 63 preferably contains TiO₂. Transmittance of the EUV light through ZrO₂ is higher than transmittance of the EUV light through TiO₂. Thus, when the photocatalyst layer 61 contains ZrO₂ and the barrier layer 63 contains TiO₂, the transmittance of the EUV light through the photocatalyst layer 61 tends to be higher than the transmittance of the EUV light through the barrier layer 63, while the photocatalyst layer 61 tends to be thicker than the barrier layer 63.

When the barrier layer 63 contains the photocatalyst as described above, the thickness of the barrier layer 63 is preferably equal to or larger than a thickness of a minimum structural unit of the photocatalyst and 5 nm or smaller. The barrier layer 63 may be thicker than the photocatalyst layer 61. Even in this case, the photocatalyst layer 61 may contain ZrO₂ and the barrier layer 63 may contain TiO₂. The barrier layer 63 may be thicker than the promotor layer 62. The barrier layer 63 preferably more reliably prevents transmission of the hydrogen radicals than the photocatalyst layer 61. In this case, a density of the barrier layer 63 is preferably higher than the density of the photocatalyst layer 61.

Such an EUV light reflective mirror 16 can be produced by, for example, repeating a deposition step several times to deposit the multilayer film 42, the barrier layer 63, the promotor layer 62, and the photocatalyst layer 61 in this order on the substrate 41. A depositing device may include, for example, a sputtering device, an atomic layer accumulating device, or the like. When the photocatalyst layer 61 is deposited and then the deposited photocatalyst layer 61 is annealed, the material of the photocatalyst layer 61 is easily polycrystallized. Thus, the photocatalyst layer 61 is preferably deposited and then annealed. When the barrier layer 63 contains the photocatalyst, the barrier layer 63 is preferably deposited and then annealed like the photocatalyst layer 61. The annealing may include laser annealing, and a laser beam used for the laser annealing may include, for example, a KrF laser beam, a XeCl laser beam, a XeF laser beam, or the like. A fluence of the laser beam is, for example, 300 to 500 mJ/cm², and a pulse width of the laser beam is, for example, 20 to 150 ns.

4.2 Effect

As described above, the hydrogen molecules contained in the gas supplied from the gas supply unit 18 are adsorbed on the surface 16A of the EUV light reflective mirror 16. When the hydrogen molecules are irradiated with light including EUV light generated when a droplet DL is turned into plasma in a plasma generating region PAL, the hydrogen molecules generate hydrogen radicals. The hydrogen radicals react with the tin fine particles moving toward the surface 16A of the EUV light reflective mirror 16 to generate stannane that is gas at room temperature.

The capping layer 53 of the EUV light reflective mirror 16 of this embodiment includes the photocatalyst layer 61 containing the photocatalyst. Thus, in the EUV light reflective mirror 16 of this embodiment, when the photocatalyst layer 61 is irradiated with the light including the EUV light, the photocatalytic ability of the photocatalyst contained in the photocatalyst layer 61 can be exhibited to easily generate the hydrogen radicals. Thus, the EUV light reflective mirror 16 can promote the reaction in Expression (1), and more tin fine particles moving toward the EUV light reflective mirror 16 can be replaced with stannane.

The capping layer 53 of the EUV light reflective mirror 16 of this embodiment is arranged between the photocatalyst layer 61 and the multilayer film 42, and includes the promotor layer 62 containing the metal for supporting the photocatalytic ability of the photocatalyst contained in the photocatalyst layer 61. Part of the tin fine particles moving toward the surface 16A of the EUV light reflective mirror 16 tend to collide with and wear away the photocatalyst layer 61. Thus, in the EUV light reflective mirror 16 of this embodiment, the promotor layer 62 may be locally exposed from the photocatalyst layer 61. In this case, the tin fine particles may collide with and wear away the exposed promotor layer 62 to diffuse the metal contained in the promotor layer 62. The diffused metal may accumulate on the photocatalyst layer 61. Alternatively, even if the promotor layer 62 is not exposed, the tin fine particles passing through the photocatalyst layer 61 may collide with the promotor layer 62 to diffuse the metal contained in the promotor layer 62. Part of the diffused metal in the promotor layer 62 may reach into the photocatalyst layer 61. In this way, when the metal in the promotor layer 62 accumulates on the photocatalyst layer 61 or reach into the photocatalyst layer 61, the metal may support the photocatalytic ability of the photocatalyst contained in the photocatalyst layer 61. Thus, when the metal contained in the promotor layer 62 is diffused, the metal may contribute to generation of more hydrogen radicals to promote the reaction in Expression (1).

In the case where the promotor layer 62 is in contact with the photocatalyst layer 61 as in this embodiment in FIG. 5, the promotor layer 62 is locally exposed from the photocatalyst layer 61 as described above to expose an interface between the photocatalyst layer 61 and the promotor layer 62. In this case, near the interface, the photocatalytic ability of the photocatalyst contained in the photocatalyst layer 61 is supported by the metal contained in the promotor layer 62. Thus, even if the photocatalyst layer 61 is locally worn away, near the exposed interface between the photocatalyst layer 61 and the promotor layer 62, the metal contained in the promotor layer 62 may contribute to generation of more hydrogen radicals to further promote the reaction in Expression (1).

The capping layer 53 of the EUV light reflective mirror 16 of this embodiment includes the barrier layer 63 arranged between the promotor layer 62 and the multilayer film 42 and configured to prevent diffusion of the metal contained in the promotor layer 62 into the multilayer film 42. This can prevent the metal contained in the promotor layer 62 from being diffused into the multilayer film 42 to contaminate the multilayer film 42 with the metal and thus to reduce reflectance. Even if the tin fine particles collide with the promotor layer 62 to diffuse the metal in the promotor layer 62 as described above, the barrier layer 63 can prevent the tin fine particles from reaching the multilayer film 42.

When the barrier layer 63 contains the photocatalyst as described above, the photocatalyst layer 61 and the promotor layer 62 are worn away by the tin fine particles to expose the barrier layer 63, and the barrier layer 63 is irradiated with the light including the EUV light, which can promote generation of the hydrogen radicals also in the barrier layer 63. Thus, also in the barrier layer 63, the reaction in Expression (1) can be promoted, and substitution of stannane for the tin fine particles moving toward the EUV light reflective mirror 16 can be promoted. When the metal contained in the promotor layer 62 supports the photocatalytic ability of the photocatalyst contained in the barrier layer 63, as described above, the diffused metal contained in the promotor layer 62 can support the photocatalytic ability of the photocatalyst contained in the barrier layer 63 to generate more hydrogen radicals. This further promotes the reaction in Expression (1). In this case, as in this embodiment in FIG. 5, the promotor layer 62 is preferably in contact with the barrier layer 63. When the barrier layer 63 is locally exposed from the photocatalyst layer 61 and the promotor layer 62, an interface between the promotor layer 62 and the barrier layer 63 is exposed. In this case, near the interface, the photocatalytic ability of the photocatalyst contained in the barrier layer 63 is supported by the metal contained in the promotor layer 62. Thus, even if the barrier layer 63 is locally exposed, near the exposed interface between the barrier layer 63 and the promotor layer 62, the metal contained in the promotor layer 62 may contribute to generation of more hydrogen radicals to further promote the reaction in Expression (1).

In this way, the EUV light reflective mirror 16 of this embodiment can prevent accumulation of the tin fine particles on the multilayer film 42, prevent diffusion of the metal contained in the promotor layer 62 into the multilayer film 42, and prevent a reduction in reflectance of the EUV light.

When the density of the promotor layer 62 is higher than the density of the photocatalyst layer 61 in this embodiment, transmission of the hydrogen radicals through the promotor layer 62 can be more reliably prevented than when the density of the promotor layer 62 is lower than the density of the photocatalyst layer 61. This can reduce transmission of the hydrogen radicals through the barrier layer 63 to reach the multilayer film 42. This can prevent occurrence of blister on an interface of the multilayer film 42.

### 5. Description of EUV Light Reflective Mirror of Embodiment 2

Next, a configuration of an EUV light reflective mirror 16 of Embodiment 2 will be described. Components similar to those described above are denoted by the same reference numerals, and overlapping descriptions are omitted unless otherwise stated.

5.1 Configuration

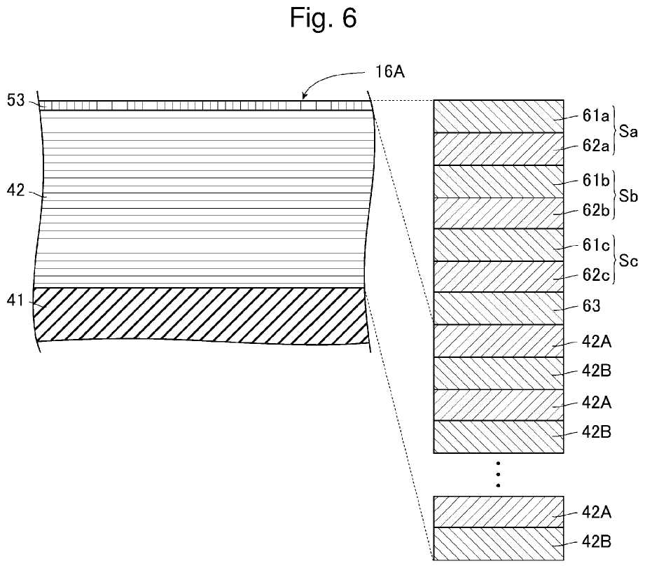

FIG. 6 diagrammatically shows a section of an EUV light reflective mirror 16 of Embodiment 2. As shown in FIG. 6, the EUV light reflective mirror 16 of this embodiment is different from the EUV light reflective mirror 16 of Embodiment 1 in that the former includes a plurality of photocatalyst layers and a plurality of promotor layers while the latter includes one photocatalyst layer 61 and one promotor layer 62.

In an example in FIG. 6, from a surface 16A toward a multilayer film 42, a photocatalyst layer 61a, a promotor layer 62a, a photocatalyst layer 61b, a promotor layer 62b, a photocatalyst layer 61c, and a promotor layer 62c are stacked in this order. The photocatalyst layer 61a, the photocatalyst layer 61b, and the photocatalyst layer 61c have the same configuration as that of the photocatalyst layer 61 of Embodiment 1. The promotor layer 62a, the promotor layer 62b, and the promotor layer 62c have the same configuration as that of the promotor layer 62 of Embodiment 1. In this embodiment, the photocatalyst layer 61a and the promotor layer 62a form a pair Sa, the photocatalyst layer 61b and the promotor layer 62b form a pair Sb, the photocatalyst layer 61c and the promotor layer 62c form a pair Sc, and the three pairs Sa to Sc are stacked on a barrier layer 63. The number of the pairs of the photocatalyst layer and the promotor layer is not limited to three, but may be two or four or more.

When the plurality of photocatalyst layers are provided as in this embodiment, a total thickness of the photocatalyst layers 61a to 61c may be larger than a total thickness of the promotor layers 62a to 62c. When transmittance of EUV light through the entire photocatalyst layers 61a to 61c is higher than transmittance of the EUV light through the barrier layer 63, the total thickness of the photocatalyst layers 61a to 61c may be larger than a thickness of the barrier layer 63. The total thickness of the photocatalyst layers 61a to 61c may be smaller than the thickness of the barrier layer 63.

Like the EUV light reflective mirror 16 of Embodiment 1, the EUV light reflective mirror 16 of this embodiment can be produced by, for example, repeating a deposition step several times using a depositing device such as a sputtering device or an atomic layer accumulating device.

5.2 Effect

As described above, hydrogen molecules contained in a gas supplied from a gas supply unit 18 are adsorbed on the photocatalyst layer 61a of the top pair Sa farthest from the multilayer film 42 in the EUV light reflective mirror 16, and the hydrogen molecules are irradiated with light including EUV light to generate hydrogen radicals. The photocatalyst layer 61a of the top pair Sa is irradiated with the light including the EUV light to cause a photocatalytic action of the photocatalyst layer 61a, thereby generating the hydrogen radicals. Tin fine particles moving toward the surface 16A of the EUV light reflective mirror 16 react with the hydrogen radicals to generate stannane that is gas at room temperature.

The tin fine particles may wear away the photocatalyst layer 61a of the top pair Sa to expose the promotor layer 62a of the pair Sa from the photocatalyst layer 61a. In this case, a photocatalytic ability of a photocatalyst in the photocatalyst layer 61a can be enhanced near the exposed part of the promotor layer 62a in the same manner as described in Embodiment 1.

Further, when the tin fine particles wear away the exposed promotor layer 62a of the top pair Sa, the photocatalyst layer 61b of the second pair Sb is exposed. Thus, as described above, a photocatalytic ability of a photocatalyst in the exposed photocatalyst layer 61b is exhibited to generate hydrogen radicals. Thus, even if the top pair Sa is worn away, stannane can be substituted for the tin fine particles.

Further, the tin fine particles may wear away the photocatalyst layer 61b of the second pair Sb to expose the promotor layer 62b of the second pair Sb. In this case, the exposed promotor layer 62b can promote the photocatalytic ability of the photocatalyst in the photocatalyst layer 61b or the photocatalyst layer 61a near the exposed part of the promotor layer 62b.

Further, when the tin fine particles wear away the exposed promotor layer 62b of the second pair Sb, the photocatalyst layer 61c of the third pair Sc is exposed. Thus, as described above, a photocatalytic ability of a photocatalyst in the exposed photocatalyst layer 61c is exhibited to generate hydrogen radicals. Thus, even if the second pair Sb is worn away, stannane can be substituted for the tin fine particles.

Further, the tin fine particles may wear away the photocatalyst layer 61c of the third pair Sc to expose the promotor layer 62c of the third pair Sc. In this case, the exposed promotor layer 62c can promote the photocatalytic ability of the photocatalyst in the photocatalyst layer 61c, the photocatalyst layer 61b, or the photocatalyst layer 61a near the exposed part of the promotor layer 62c.

In this way, in the EUV light reflective mirror 16 of this embodiment, the photocatalyst layer and the promotor layer form the pair, and the plurality of pairs are stacked on the barrier layer 63. Thus, even if at least part of the photocatalyst layer 61a and the promotor layer 62a of the top pair Sa farthest from the multilayer film 42 are worn away, the photocatalyst layer and the promotor layer of the pair closer to the multilayer film 42 than the top pair can substitute stannane for the tin fine particles. Thus, the EUV light reflective mirror 16 of this embodiment can more reliably prevent accumulation of the tin fine particles and increase life of the EUV light reflective mirror 16 than the EUV light reflective mirror 16 of Embodiment 1 including one pair.

When densities of the promotor layers 62a to 62c of the plurality of pairs Sa to Sc are higher than densities of the photocatalyst layers 61a to 61c, the promotor layers 62a to 62c can prevent transmission of the hydrogen radicals. This can more reliably reduce transmission of the hydrogen radicals through the barrier layer 63 to reach the multilayer film 42 and prevent occurrence of blister on an interface of the multilayer film 42 than in Embodiment 1 including one promotor layer 62.

### 6. Description of EUV Light Reflective Mirror of Embodiment 3

Next, a configuration of an EUV light reflective mirror 16 of Embodiment 3 will be described. Components similar to those described above are denoted by the same reference numerals, and overlapping descriptions are omitted unless otherwise stated.

6.1 Configuration

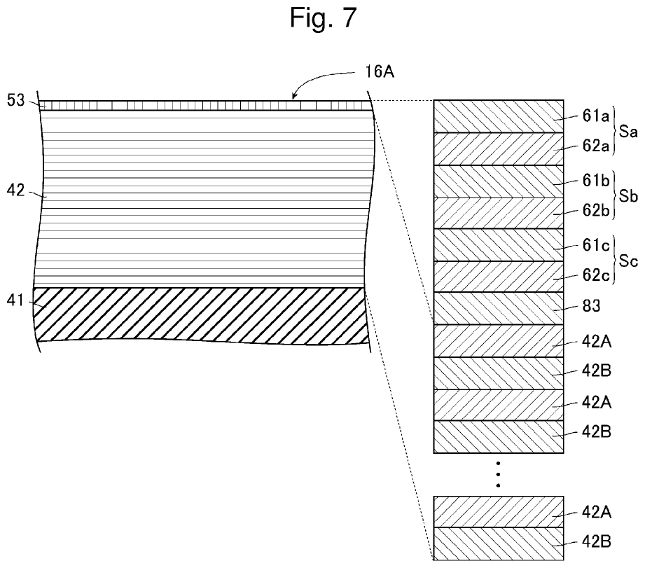

FIG. 7 diagrammatically shows a section of an EUV light reflective mirror 16 of Embodiment 3. As shown in FIG. 7, the EUV light reflective mirror 16 of Embodiment 3 is different from the EUV light reflective mirror 16 of Embodiment 2 in including a barrier layer 83 instead of the barrier layer 63.

The barrier layer 83 of this embodiment prevents diffusion of a metal contained in promotor layers 62a to 62c into a multilayer film 42, and more reliably prevents transmission of hydrogen radicals than the promotor layers 62a to 62c. The barrier layer 83 may contain, for example, any of an oxide of a lanthanoid metal, a nitride of the lanthanoid metal, and a boride of the lanthanoid metal. As long as the barrier layer 83 mainly contains such a material, the barrier layer 83 may contain, together with the material, additives, impurities, or the like in a smaller amount than the material. The lanthanoid metal may be selected from La, Ce, Eu, Tm, Gd, Yb, Pr, Tb, Lu, Nd, Dy, Pm, Ho, Sm, or Er. The oxide of the lanthanoid metal may include, for example, La₂O₃, CeO₂, Eu₂O₃, TmO₃, Gd₂O₃, Yb₂O₃, Pr₂O₃, Tb₂O₃, Lu₂O₃, Nd₂O₃, Dy₂O₃, Pm₂O₃, Ho₂O₃, Sm₂O₃, or Er₂O₃. Densities of these compounds are as described below. Specifically, the density of La₂O₃ is 6.51 g/cm³. The density of CeO₂ is 7.22 g/cm³. The density of Eu₂O₃ is 7.42 g/cm³. The density of TmO₃ is 8.6 g/cm³. The density of Gd₂O₃ is 7.41 g/cm³. The density of Yb₂O₃ is 9.17 g/cm³. The density of Pr₂O₃ is 6.9 g/cm³. The density of Tb₂O₃ is 7.9 g/cm³. The density of Lu₂O₃ is 9.42 g/cm³. The density of Nd₂O₃ is 7.24 g/cm³. The density of Dy₂O₃ is 7.8 g/cm³. The density of Pm₂O₃ is 6.85 g/cm³. The density of Ho₂O₃ is 8.41 g/cm³. The density of Sm₂O₃ is 8.35 g/cm³. The density of Er₂O₃ is 8.64 g/cm³. The nitride of the lanthanoid metal may include, for example, LaN, CeN, PrN, NdN, PmN, SmN, EuN, GdN, TbN, DyN, HoN, ErN, TmN, YbN, or LuN. A density of SmN is 7.353 g/cm³. A density of TmN is 9.321 g/cm³. A density of YbN is 6.57 g/cm³. The boride of the lanthanoid metal may include, for example, LaB₆, CeB₆, PrB₆, NdB₆, PmB₆, SmB₆, EuB₆, GdB₆, TbB₆, DyB₆, HoB₆, ErB₆, TmB₆, YbB₆, or LuB₆. A density of LaB₆ is 2.61 g/cm³. A density of CeB₆ is 4.8 g/cm³. A density of NdB₆ is 4.93 g/cm³. A density of SmB₆ is 5.07 g/cm³.

The barrier layer 83 may contain any of an oxide, a nitride, and a boride containing a metal of any of Y, Zr, Nb, Hf, Ta, W, Re, Os, Ir, Sr, and Ba. The metal is preferably selected from Y, Zr, Nb, Hf, Ta, or W. As long as the barrier layer 83 mainly contains such a material, the barrier layer 83 may contain, together with the material, additives, impurities, or the like in a smaller amount than the material. The oxide containing the metal may include, for example, Y₂O₃, ZrO₂, Nb₂O₅, HfO₂, Ta₂O₅, WO₃, ReO₃, OsO₄, IrO₂, SrO, or BaO. Densities of these compounds are as described below. Specifically, the density of Y₂O₃ is 5.01 g/cm³. The density of ZrO₂ is 5.68 g/cm³. The density of Nb₂O₅ is 4.6 g/cm³. The density of HfO₂ is 9.68 g/cm³. The density of Ta₂O₅ is 8.2 g/cm³. The density of WO₂ is 10.98 g/cm³. The density of ReO₃ is 6.92 g/cm³. The density of OsO₄ is 4.91 g/cm³. The density of IrO₂ is 11.66 g/cm³. The density of SrO is 4.7 g/cm³. The density of BaO is 5.72 g/cm³. The nitride containing the metal may include, for example, YN, ZrN, NbN, HfN, TaN, or WN. Densities of these compounds are as described below. Specifically, the density of YN is 5.6 g/cm³. The density of ZrN is 7.09 g/cm³. The density of NbN is 8.47 g/cm³. The density of HfN is 13.8 g/cm³. The density of TaN is 13.7 g/cm³. The density of WN is 5.0 g/cm³. The boride containing the metal may include, for example, BaB₆, YB₆, ZrB₂, NbB₂, TaB, HfB₂, WB, or ReB₂. Densities of these compounds are as described below. Specifically, the density of BaB₆ is 4.36 g/cm³. The density of YB₆ is 3.67 g/cm³. The density of ZrB₂ is 6.08 g/cm³. The density of NbB₂ is 6.97 g/cm³. The density of TaB is 14.2 g/cm³. The density of HfB₂ is 10.5 g/cm³. The density of WB is 15.3 g/cm³. The density of ReB₂ is 12.7 g/cm³.

A thickness of the barrier layer 83 is preferably equal to or larger than a thickness of a minimum structural unit of a compound of a metal and a non-metal contained in the barrier layer 83 and 5 nm or smaller. A density of the barrier layer 83 is preferably higher than densities of the promotor layers 62a to 62c.

Like the EUV light reflective mirror 16 of Embodiment 1, the EUV light reflective mirror 16 of this embodiment can be produced by, for example, repeating a deposition step several times using a depositing device such as a sputtering device or an atomic layer accumulating device.

6.2 Effect

Also in this embodiment, as in Embodiment 2, photocatalyst layers 61 of a plurality of pairs Sa to Sc can each exhibit a photocatalytic ability of a photocatalyst to generate hydrogen radicals. The hydrogen radicals may reach the barrier layer 83 due to collision with tin fine particles moving toward the EUV light reflective mirror 16, or the like. However, the barrier layer 83 of this embodiment prevents diffusion of the metal contained in the promotor layers 62a to 62c into the multilayer film 42, and more reliably prevents transmission of the hydrogen radicals than the promotor layers 62a to 62c. This can prevent the hydrogen radicals having reached the barrier layer 83 from passing through the barrier layer 83 to reach the multilayer film 42. Thus, the EUV light reflective mirror 16 of this embodiment can prevent occurrence of blister on an interface of the multilayer film 42. This embodiment has been described with the example in which the EUV light reflective mirror 16 includes the barrier layer 83 instead of the barrier layer 63 of Embodiment 2, but the EUV light reflective mirror 16 may include the barrier layer 83 instead of the barrier layer 63 of Embodiment 1.

The above descriptions are intended to be illustrative only and not restrictive. Thus, it will be apparent to those skilled in the art that modifications may be made in the embodiments or variants of the present disclosure without departing from the scope of the appended claims.

The terms used throughout the specification and the appended claims should be interpreted as “non-limiting.” For example, the term “comprising” or “comprised” should be interpreted as “not limited to what has been described as being comprised.” The term “having” should be interpreted as “not limited to what has been described as having.” Further, the modifier “a/an” described in the specification and the appended claims should be interpreted to mean “at least one” or “one or more.”

What is claimed is:

1. A mirror for extreme ultraviolet light comprising:
a substrate;
a multilayer film provided on the substrate and configured to reflect extreme ultraviolet light; and
a capping layer provided on the multilayer film,
the capping layer including
a photocatalyst layer containing a photocatalyst,
a promotor layer arranged between the photocatalyst layer and the multilayer film and containing a metal for supporting a photocatalytic ability of the photocatalyst contained in the photocatalyst layer, and
a barrier layer arranged between the promotor layer and the multilayer film and configured to prevent diffusion of the metal into the multilayer film.

2. The mirror for extreme ultraviolet light according to claim 1, wherein a thickness of the promotor layer is smaller than a thickness of the photocatalyst layer.

3. The mirror for extreme ultraviolet light according to claim 1, wherein a thickness of the photocatalyst layer is larger than a thickness of the barrier layer.

4. The mirror for extreme ultraviolet light according to claim 3, wherein transmittance of the extreme ultraviolet light through the photocatalyst layer is higher than transmittance of the extreme ultraviolet light through the barrier layer.

5. The mirror for extreme ultraviolet light according to claim 1, wherein a thickness of the photocatalyst layer is equal to or larger than a thickness of a minimum structural unit of the photocatalyst contained in the photocatalyst layer and 5 nm or smaller.

6. The mirror for extreme ultraviolet light according to claim 1, wherein a thickness of the promotor layer is equal to or larger than an atomic diameter of the metal contained in the promotor layer and 2 nm or smaller.

7. The mirror for extreme ultraviolet light according to claim 1, wherein
the capping layer includes a plurality of pairs of the photocatalyst layer and the promotor layer, and
the barrier layer is arranged between the pairs and the multilayer film.

8. The mirror for extreme ultraviolet light according to claim 7, wherein a total thickness of the photocatalyst layers of the pairs is larger than a total thickness of the promotor layers of the pairs.

9. The mirror for extreme ultraviolet light according to claim 1, wherein the barrier layer contains a photocatalyst.

10. The mirror for extreme ultraviolet light according to claim 9, wherein the metal contained in the promotor layer supports a photocatalytic ability of the photocatalyst contained in the barrier layer.

11. The mirror for extreme ultraviolet light according to claim 10, wherein the photocatalyst contained in the barrier layer and the photocatalyst contained in the photocatalyst layer are made of the same material.

12. The mirror for extreme ultraviolet light according to claim 9, wherein the photocatalyst contained in the barrier layer and the photocatalyst contained in the photocatalyst layer are made of different materials.

13. The mirror for extreme ultraviolet light according to claim 12, wherein the photocatalyst layer contains ZrO₂, and the barrier layer contains TiO₂.

14. The mirror for extreme ultraviolet light according to claim 1, wherein the barrier layer more reliably prevents transmission of hydrogen radicals than the promotor layer.

15. The mirror for extreme ultraviolet light according to claim 14, wherein the barrier layer contains any of an oxide of a lanthanoid metal, a nitride of the lanthanoid metal, and a boride of the lanthanoid metal.

16. The mirror for extreme ultraviolet light according to claim 14, wherein the barrier layer contains any of an oxide, a nitride, and a boride containing a metal of any of Y, Zr, Nb, Hf, Ta, W, Re, Os, Ir, Sr, and Ba.

17. The mirror for extreme ultraviolet light according to claim 1, wherein the photocatalyst contained in the photocatalyst layer has a polycrystalline structure.

18. The mirror for extreme ultraviolet light according to claim 1, wherein the photocatalyst layer contains any of TiO₂, ZrO₂, Fe₂O₃, Cu₂O, In₂O₃, WO₃, Fe₂TiO₃, PbO, V₂O₅, FeTiO₃, Bi₂O₃, Nb₂O₃, SrTiO₃, ZnO, BaTiO₃, CaTiO₃, KTiO₃, and SnO₂.

19. The mirror for extreme ultraviolet light according to claim 1, wherein the promotor layer contains any of Ru, Rh, Pd, Os, Ir, and Pt.

20. An extreme ultraviolet light generating apparatus comprising:
a chamber;
a droplet discharge unit configured to discharge a droplet of a target substance into the chamber; and
a mirror for extreme ultraviolet light provided in the chamber,
the mirror for extreme ultraviolet light including a substrate, a multilayer film provided on the substrate and configured to reflect extreme ultraviolet light, and a capping layer provided on the multilayer film,
the capping layer including a photocatalyst layer containing a photocatalyst, a promotor layer arranged between the photocatalyst layer and the multilayer film and containing a metal for supporting a photocatalytic ability of the photocatalyst contained in the photocatalyst layer, and a barrier layer arranged between the promotor layer and the multilayer film and configured to prevent diffusion of the metal into the multilayer film.
